(19) United States
(12) Patent Application Publication
(10) Pub. No.: US 2025/0107145 A1
(43) Pub. Date: Mar. 27, 2025

(54) Semiconductor device and method of manufacturing the same

(71) Applicant: ARK MICROELECTRONIC CORP. LTD., Shenzhen (CN)

(72) Inventor: Chin-Fu Chen, Hsinchu County (TW)

(73) Assignee: ARK MICROELECTRONIC CORP. LTD, Shenzhen (CN)

(21) Appl. No.: 18/889,433

(22) Filed: Sep. 19, 2024

(30) Foreign Application Priority Data
Sep. 26, 2023 (CN) 202311254420.8

(51) Int. Cl. H01L 29/78; H01L 29/06; H01L 29/08; H01L 29/10; H01L 29/40; H01L 29/66

(52) U.S. Cl. CPC H10D 30/668; H10D 30/0297; H10D 62/127; H10D 62/154; H10D 62/393; H10D 64/117

(57) ABSTRACT

A semiconductor device comprises an epitaxial layer, a first trench, a first field plate, a first trench gate, a first planar gate, and a first conductive connection portion. The first trench is disposed in the epitaxial layer and extends along a first direction. The first field plate is disposed in the first trench and extends along the first direction. The first trench gate is disposed in the first trench and extends along the first direction, where the first trench gate is laterally separated from the first field plate. The first planar gate is disposed on the first field plate and the first trench gate. The first conductive connection portion is disposed in the first trench and located between the first trench gate and the first planar gate, and the first trench gate is electrically connected to the first planar gate through the first conductive connection portion.

### BACKGROUND OF THE INVENTION

### 1. Field of the Invention

The present disclosure relates to a semiconductor technology, especially to a semiconductor device including a power transistor with both a trench gate and a planar gate, and a method of manufacturing the same.

### 2. Description of the Prior Art

A power transistor refers to a transistor that operates under conditions of high voltage and high current. The most common power transistor is a power metal oxide semiconductor field effect transistor (power MOSFET), which can be used in many different fields, such as power supplies, DC-to-DC converters, low-voltage motor controllers, etc.

In recent years, with the development of various electronic products, the power and layout density of power MOSFET have also increased, and the frequency applied to DC-to-DC converters has also increased significantly. At present, the technology of power MOSFET, such as split gate trench (SGT), Laterally-Diffused Metal-Oxide Semiconductor (LDMOS), and U-shaped trench Metal-Oxide Semiconductor (UMOS), are difficult to fully meet the requirements of electronic products in all aspects, such requirements are, for example, reducing chip area, increasing device layout density, increasing current, and reducing switching loss. Therefore, the industry urgently needs to develop new power transistors to overcome the above problems.

### SUMMARY OF THE INVENTION

In view of this, the present disclosure provides a semiconductor device including a power transistor with both a trench gate and a planar gate to meet various requirements when applied to electronic products.

According to an embodiment of the present disclosure, a semiconductor device comprises an epitaxial layer, a first trench, a first field plate, a first trench gate, a first planar gate, and a first conductive connection portion. The epitaxial layer is of a first conductivity type. The first trench is disposed in the epitaxial layer and extends along a first direction. The first field plate is disposed in the first trench and extends along the first direction. The first trench gate is disposed in the first trench and extends along the first direction, where the first trench gate is laterally separated from the first field plate, and a top surface of the first field plate is higher than a top surface of the first trench gate. The first planar gate is disposed on the first field plate and the first trench gate, and the first planar gate extends along a second direction which is not parallel to the first direction. The first conductive connection portion is disposed in the first trench and located between the first trench gate and the first planar gate, and the first trench gate is electrically connected to the first planar gate through the first conductive connection portion.

According to an embodiment of the present disclosure, a manufacturing method of a semiconductor device includes: providing a first trench structure, where the first trench structure is located in an epitaxial layer and extends along a first direction, and the first trench structure includes a first trench, a first field plate disposed in the first trench, and a trench dielectric layer disposed between the first trench and the first field plate; etching the trench dielectric layer to form a first recess extending along a first direction; forming a conductive layer to fill the first recess, where the conductive layer covers the first field plate and the epitaxial layer; etching the conductive layer to form a first trench gate, a first planar gate, and a first conductive connection portion. The first trench gate extends along the first direction and is laterally separated from the first field plate. The first planar gate extends along a second direction which is not parallel to the first direction, where the first planar gate is disposed on the first field plate and the first trench gate. The first conductive connection portion is disposed in the first recess and located between the first trench gate and the first planar gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic perspective view of a partial region of a semiconductor device according to an embodiment of the present disclosure.

FIG. 2 is a schematic cross-sectional view taken along section line AA′ in FIG. 1 according to an embodiment of the present disclosure.

FIG. 3 is a schematic cross-sectional view taken along section line BB′ in FIG. 1 according to an embodiment of the present disclosure.

FIG. 4 is a schematic cross-sectional view taken along section line CC′ of FIG. 1 according to an embodiment of the present disclosure.

FIG. 5 is a schematic cross-sectional view taken along section line DD′ of FIG. 1 according to an embodiment of the present disclosure.

FIG. 6 is a schematic perspective view of a semiconductor device including two repeating units according to an embodiment of the present disclosure.

FIG. 7 is a schematic cross-sectional view taken along section line EE′ of FIG. 6 according to an embodiment of the present disclosure.

FIG. 8 is a schematic perspective view of various stages of a manufacturing method of a semiconductor device according to an embodiment of the present disclosure.

FIG. 9 is a schematic perspective view of various stages of a manufacturing method of a semiconductor device according to an embodiment of the present disclosure.

FIG. 10 is a schematic top view of a semiconductor device including at least two repeating units according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

Although this disclosure uses the terms first, second, third, etc. to describe various elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer, or block discussed below can also be referred to as the second element, component, region, layer, or block without departing from the specific embodiments of this disclosure.

The term “about” or “substantially” mentioned in this disclosure usually means within 20%, preferably within 10%, and more preferably within 5%, or within 3%, or within 28, or within 18, or within 0.5% of a given value or range. It should be noted that the quantity provided in the specification is approximate, that is, the meaning of “about” or “substantially” can still be implied without specifying “about” or “substantially”.

The terms “coupled” and “electrically connected” mentioned in this disclosure include any direct and indirect means of electrical connection. For example, if the first component is described as being coupled to the second component, it means that the first component can be directly electrically connected to the second component, or indirectly electrically connected to the second component through other devices or connecting means.

Although the disclosure is described with respect to specific embodiments, the principles of the disclosure, as defined by the claims appended herein, may obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

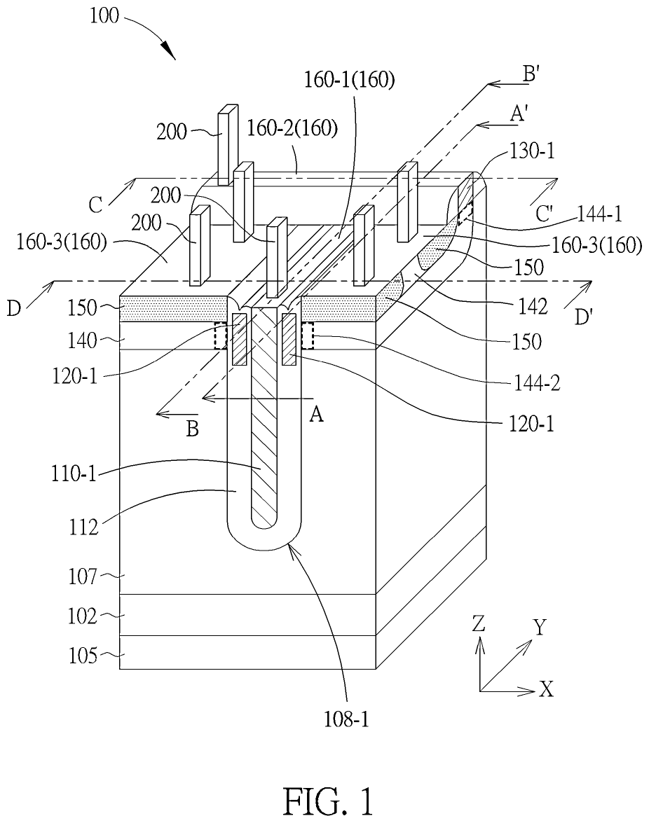

FIG. 1 is a schematic perspective view of a partial region of a semiconductor device according to an embodiment of the present disclosure. As shown in FIG. 1, in one embodiment, the semiconductor device 100 includes a substrate 102 that is of a first conductivity type, such as an N⁺ substrate, and an epitaxial layer 107 that is disposed on the substrate 102 and is of the first conductivity type, such as an N-type silicon epitaxial layer (N epitaxial layer). The epitaxial layer 107 can function as a drift region.

The semiconductor device 100 further includes a first trench 108-1, which is disposed in the epitaxial layer 107 and extends along a first direction, such as the Y-direction. According to an embodiment, a first field plate 110-1, at least one first trench gate 120-1 (for example, two first trench gates 120-1), and a trench dielectric layer 112 are disposed in the first trench 108-1.

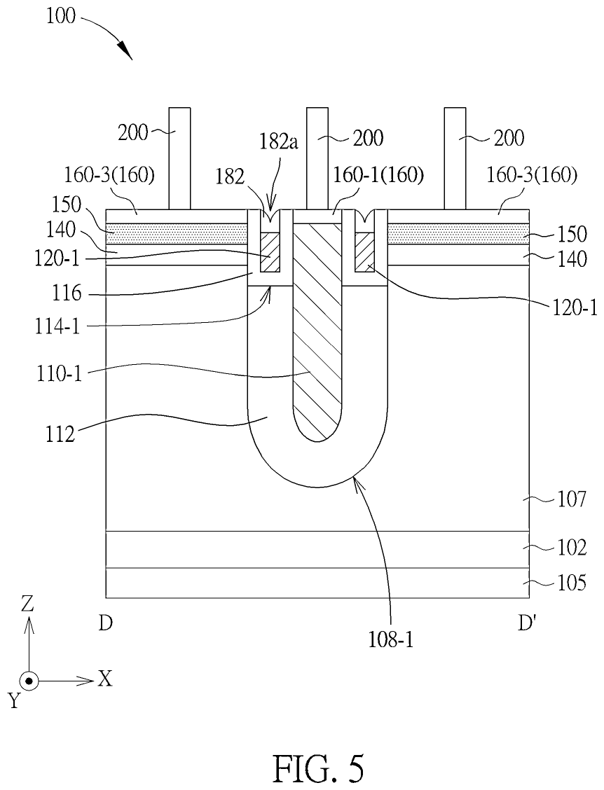

The first field plate 110-1 is disposed in the first trench 108-1 and extends along the first direction, such as the Y-direction. The first trench gate 120-1 (see FIG. 5) is disposed in the first trench 108-1 and extends along the first direction, where the first trench gate 120-1 is laterally (for example, in the X-direction) separated from the first field plate 110-1, and a top surface of the first field plate 110-1 is higher than a top surface of the first trench gate 120-1. According to an embodiment, the first trench 108-1 includes two first trench gates 120-1, which are respectively disposed on both sides of the first field plate 110-1.

The trench dielectric layer 112 is disposed in the first trench 108-1 and located between an inner surface of the first trench 108-1 and the first field plate 110-1. The trench dielectric layer 112 may be formed of silicon oxide, silicon nitride, silicon oxynitride or a dielectric material with a high dielectric constant.

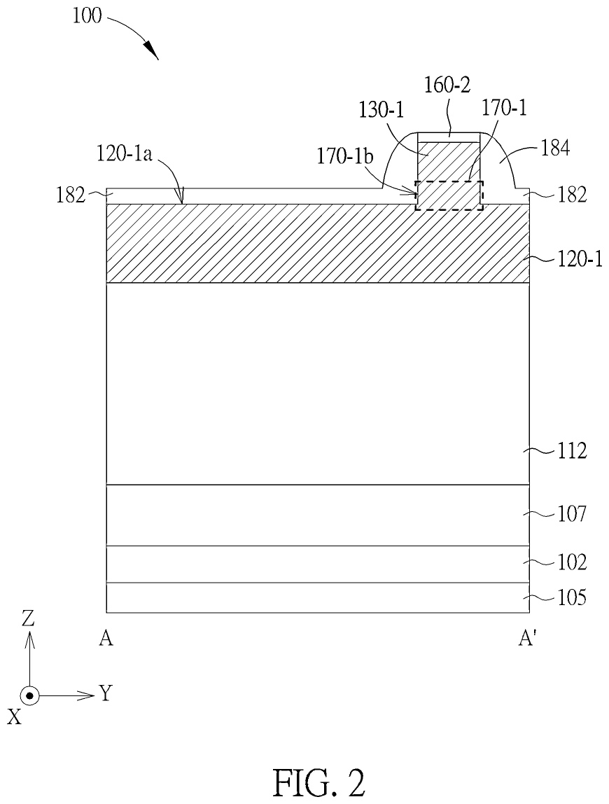

A first planar gate 130-1 is disposed above the first field plate 110-1 and the first trench gate 120-1, and extends along a second direction, such as the X-direction, which is not parallel to the first direction. The first planar gate 130-1 may be electrically connected to the first trench gate 120-1 via a conductive connection portion (for example, a first conductive connection portion 170-1 shown in FIG. 2) disposed in the first trench 108-1, so that the first planar gate 130-1 and the first trench gate 120-1 may turn-on and turn-off the semiconductor device synchronously.

According to an embodiment, the first trench gate 120-1, the first planar gate 130-1 and the first conductive connection portion 170-1 are made of conductive materials, such as doped conductive polysilicon or other conductive semiconductors, and the materials of the first trench gate 120-1, the first planar gate 130-1 and the first conductive connection portion 170-1 are the same, but not limited thereto.

According to an embodiment, the semiconductor device 100 further includes a body doped region 140 disposed in the epitaxial layer 107, and the body doped region 140 is of a second conductivity type opposite to the first conductivity type, such as a p-body region, where the dopant concentration of the second conductivity type dopant in the body doped region 140 is higher than the dopant concentration of the first conductivity type dopant in the epitaxial layer 107. The body doped region 140 extends outside a sidewall of the first trench 108-1 in the second direction (for example, in the X-direction), so that a portion of the body doped region 140 covers a side of the first trench gate 120-1, and another portion of the body doped region 140 is covered by the first planar gate 130-1 in the vertical direction (for example, in the Z-direction).

The semiconductor device 100 further includes at least one source doped region 150 disposed in the upper portion of the epitaxial layer 107 and abutting the first trench 108-1, and the source doped region 150 is of the first conductivity type. According to an embodiment, the semiconductor device 100 includes two source doped regions 150, which are disposed in the body doped region 140 and abut the first trench 108-1. The source doped regions 150 are separated from each other along the first direction (for example, in the Y-direction), and the source doped regions 150 are of the first conductivity type, such as the N-type heavily doped regions. One of the source doped regions 150 is adjacent to the first planar gate 130-1, and the other one of the source doped regions 150 is adjacent to another planar gate (not shown). Since the source doped region 150 occupies the upper portion of the body doped region 140 by ion implantation, the source doped region 150 can be regarded as being disposed in or on the body doped region 140 (that is, a portion of the body doped region 140 may be regarded as being disposed below the source doped region 150).

The semiconductor device 100 further includes a body contact region 142 disposed between two source doped regions 150. The body contact region 142 is of the second conductivity type, such as the p-type heavily doped region, and the doping concentration of the p-type dopant of the body contact region 142 is higher than the doping concentration of the p-type dopant of the body doped region 140. The body contact region 142 is electrically connected to the body doped region 140 to control the electric potential of the body doped region 140.

The semiconductor device 100 further includes a plurality of conductive compounds 160 laterally separated from each other, such as a first conductive compound 160-1, a second conductive compound 160-2, and a third conductive compound 160-3. The first conductive compound 160-1 is electrically connected to the first field plate 110-1, the second conductive compound 160-2 is electrically connected to the first planar gate 130-1, and the third conductive compound 160-3 is electrically connected to the source doped region 150 and the body contact region 142. The conductive compound 160 may be a compound including metal and semiconductor, such as nickel silicide or other metal silicide. The resistivity of the conductive compound 160 is lower than the resistivity of the first field plate 110-1, the first planar gate 130-1, the source doped region 150, and the body contact region 142, thereby reducing the on-resistance, signal delay, and switching loss. By using the conductive compound 160 with low resistivity, even if the vertical projection area of the semiconductor device 100 continues to shrink, the current can still be transmitted through the conductive compound 160 without incurring current transmission loss due to the miniaturization of components.

Regarding the first conductive compound 160-1, the first conductive compound 160-1 covers the top surface of the first field plate 110-1 and extends along the first direction, such as the Y direction. The two first trench gates 120-1 on both sides of the first field plate 110-1 are laterally (for example, in the X direction) separated from the first conductive compound 160-1 and are not electrically connected to the first trench gates 120-1.

Regarding the second conductive compound 160-2, the second conductive compound 160-2 covers the top surface of the first planar gate 130-1 and extends along the second direction, such as the X-direction. The second conductive compound 160-2 is separated from the first conductive compound 160-1 in the vertical direction (for example, in the Z-direction) and lateral direction (for example, in the X-direction) without being electrically connected to the first conductive compound 160-1.

Regarding the third conductive compound 160-3, the third conductive compound 160-3 is a continuously distributed single conductive compound, covering the top surfaces of the source doped regions 150 which are separated from each other in the first direction, and covering the top surfaces of the body contact regions 142 between the source doped regions 150. The third conductive compound 160-3 is laterally separated from the first trench gate 120-1 and the first conductive compound 160-1. Further, the third conductive compound 160-3 is laterally separated (for example, in the X-direction) from the first conductive compound 160-1 without being electrically connected to the first conductive compound 160-1. In addition, the third conductive compound 160-3 is laterally separated (for example, in the Y-direction) from the second conductive compound 160-2 without being electrically connected to the second conductive compound 160-2.

The semiconductor device 100 further includes a plurality of conductive contact structures 200 that are disposed separately from each other. By arranging the conductive contact structure 200, external signals can be transmitted to the corresponding first field plate 110-1, first planar gate 130-1 and source doped region 150. Specifically, at least one of the conductive contact structures 200 is electrically connected to the first conductive compound 160-1 and further electrically connected to the first field plate 110-1. At least another one of the conductive contact structures 200 is electrically connected to the second conductive compound 160-2 and further electrically connected to the first planar gate 130-1. At least two other conductive contact structures 200 are respectively disposed on the corresponding source doped regions 150 and electrically connected to the third conductive compound 160-3, and further electrically connected to the source doped region 150 and the body contact region 142.

For the conductive contact structure 200 that is electrically connected to the source doped region 150, since the conductive contact structure 200 can be electrically connected to the source doped regions 150 and the body contact regions 142 through the third conductive compound 160-3 disposed on the epitaxial layer 107, it is unnecessary for the bottom surface of the conductive contact structure 200 to penetrate into the epitaxial layer 107, thus the conductive contact structure 200 can be integrated into other semiconductor device processes, such as complementary field-effect transistor or bipolar junction transistor, to simplify the whole process.

When the semiconductor device 100 is in on-state, the first planar gate 130-1 and the first trench gate 120-1 are positively biased, so that an on-state channel region is generated in the adjacent body doped region 140, for example, a horizontal channel region 144-1 generated abutting the first planar gate 130-1 and a vertical channel region 144-2 generated abutting the first trench gate 120-1. Therefore, the current from the drain terminal can sequentially flow through the epitaxial layer 107, the channel region (the horizontal channel region 144-1 and the vertical channel region 144-2), and the source doped region 150 from bottom to top, and finally enter the corresponding conductive contact structure 200. In addition, the first field plate 110-1 may be applied with a positive bias, which may be the same as or different from the positive bias applied to the first planar gate 130-1 and the first trench gate 120-1. By applying a positive bias to the first field plate 110-1, the electric field distribution around the first trench 108-1 can be adjusted, thereby avoiding the electrical breakdown of the semiconductor device 100 or further reducing the on-resistance.

FIG. 2 is a schematic cross-sectional view taken along section line AA′ of FIG. 1 according to an embodiment of the present disclosure. As shown in FIG. 2, the first trench gate 120-1 extends along the first direction, such as the Y-direction, and the first conductive connection portion 170-1 is disposed between the first trench gate 120-1 and the first planar gate 130-1, so that the first trench gate 120-1 is electrically connected to the first planar gate 130-1 through the first conductive connection portion 170-1. The top surface of the first planar gate 130-1 is covered with the second conductive compound 160-2, so that the current can be transmitted to the regions of the first planar gate 130-1 along the second direction through the second conductive compound 160-2.

In addition, the semiconductor device 100 further includes a trench gate cap layer 182, which covers the top surface 120-1a of the first trench gate 120-1 and a side surface 170-1b of the first conductive connection portion 170-1. The semiconductor device 100 further includes planar gate spacers 184 covering two opposite sides of the first planar gate 130-1. The planar gate spacers 184 extend along the second direction, such as the X-direction, and are disposed on the first trench 108-1. The trench gate cap layer 182 and the planar gate spacers 184 can be formed by depositing a dielectric layer and through self-aligned etching, so the materials of the trench gate cap layer 182 and the planar gate spacers 184 may be the same, such as silicon oxide, silicon nitride, silicon oxynitride or other suitable dielectric materials.

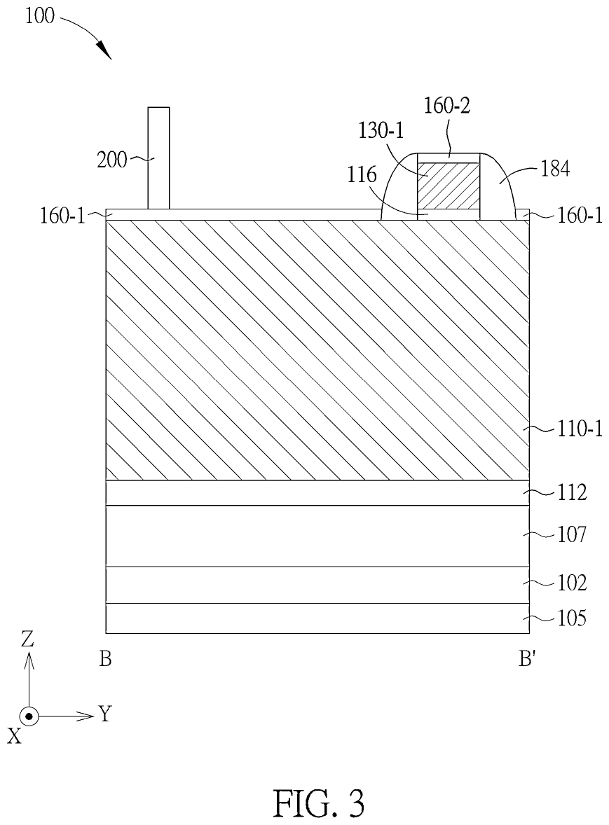

FIG. 3 is a schematic cross-sectional view taken along section line BB′ in FIG. 1 according to an embodiment of the present disclosure. As shown in FIG. 3, the first field plate 110-1 extends along the first direction, such as the Y-direction, and the top surface of the first field plate 110-1 is covered with the first conductive compound 160-1 and electrically connected to the conductive contact structure 200. By providing the first conductive compound 160-1, the current can be transmitted to every region in the first field plate 110-1 along the first direction through the first conductive compound 160-1.

The first planar gate 130-1 is disposed on the first field plate 110-1, and a gate dielectric layer 116 is included between the first planar gate 130-1 and the first field plate 110-1. By providing the gate dielectric layer 116, the first planar gate 130-1 can be prevented from being electrically connected to the first field plate 110-1. The gate dielectric layer 116 may include silicon oxide, silicon nitride, silicon oxynitride or a dielectric material with a high dielectric constant.

The planar gate spacers 184 are disposed on two opposite sides of the first planar gate 130-1, so that the first conductive compound 160-1 and the second conductive compound 160-2 are separated from each other. Since the planar gate spacer 184 is an insulating material, the first conductive compound 160-1 can be prevented from being electrically connected to the second conductive compound 160-2.

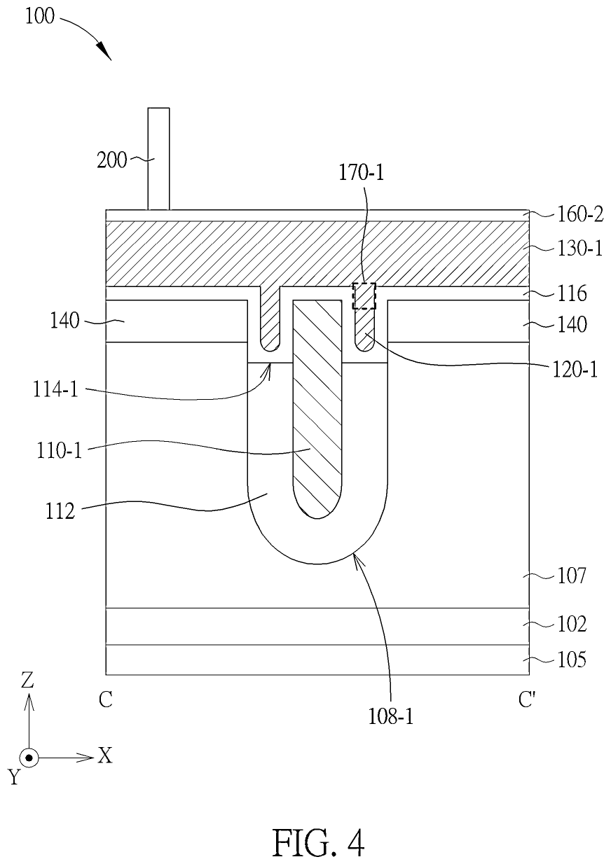

FIG. 4 is a schematic cross-sectional view taken along section line CC′ in FIG. 1 according to an embodiment of the present disclosure. As shown in the later process steps, the trench dielectric layer 112 is disposed in the lower portion of the first trench 108-1. The upper portion of the first trench 108-1 that is not covered by the trench dielectric layer 112 forms two first recesses 114-1 on both sides of the first field plate 110-1. The continuous gate dielectric layer 116 is provided on the inner surface of the first recess 114-1, and the gate dielectric layer 116 extends out from the first recess 114-1 to cover the top surface of the body doped region 140. Each of the first recesses 114-1 further includes the first trench gate 120-1 and the first conductive connection portion 170-1. The first trench gate 120-1 can be electrically connected to the first planar gate 130-1 through the first conductive connection portion 170-1. The conductive contact structure 200 is disposed on the first planar gate 130-1 and electrically connected to the first planar gate 130-1.

FIG. 5 is a schematic cross-sectional view taken along section line DD′ of FIG. 1 according to an embodiment of the present disclosure. As shown in FIG. 5, each first recess 114-1 includes the gate dielectric layer 116, the first trench gate 120-1, and the trench gate cap layer 182. The trench gate cap layer 182 covers the top surface of the first trench gate 120-1, and the trench gate cap layer 182 includes a recessed top surface 182a.

Two body doped regions 140, two source doped regions 150, and two third conductive compounds 160-3 are respectively disposed on both sides of the first trench 108-1. The bottom surface of the body doped region 140 is higher than the bottom surface of the first trench gate 120-1, and the bottom surface of the source doped region 150 is lower than the top surface of the first trench gate 120-1. Consequently, in the depth direction (for example, in the Z-direction) of the semiconductor device 100, the top surface of the first trench gate 120-1 is higher than the top surface of the body doped region 140, and the bottom surface of the first trench gate 120-1 is lower than the bottom surface of the body doped region 140.

The first conductive compound 160-1 and the third conductive compound 160-3 are laterally (for example, in the X-direction) separated from each other and electrically insulated from each other.

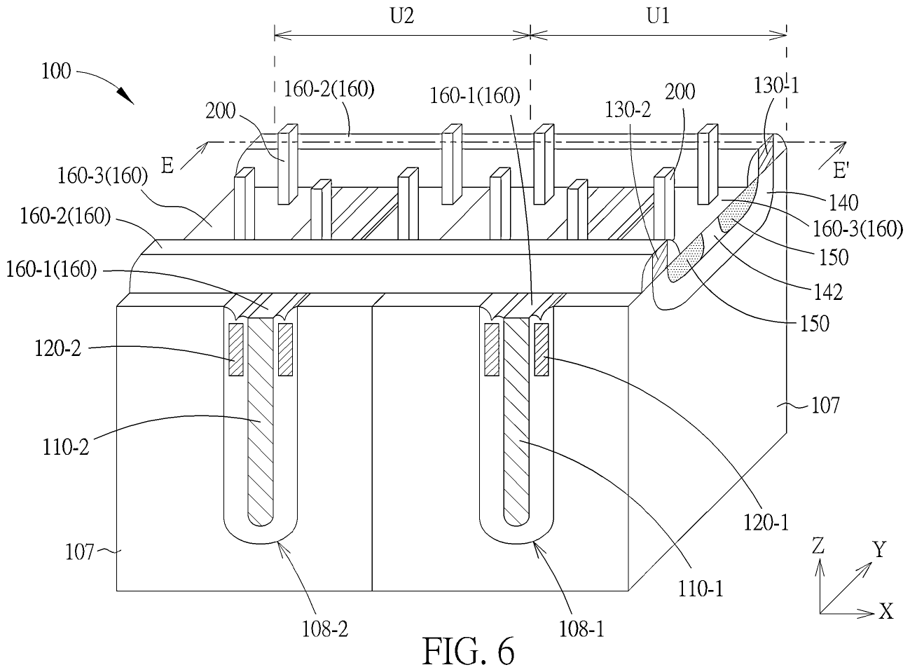

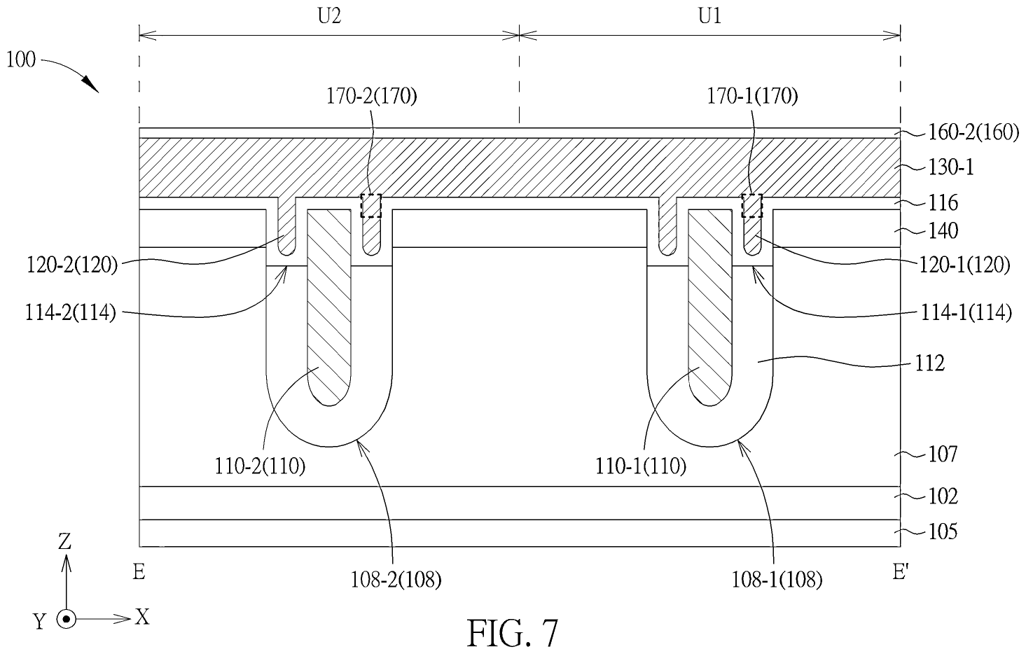

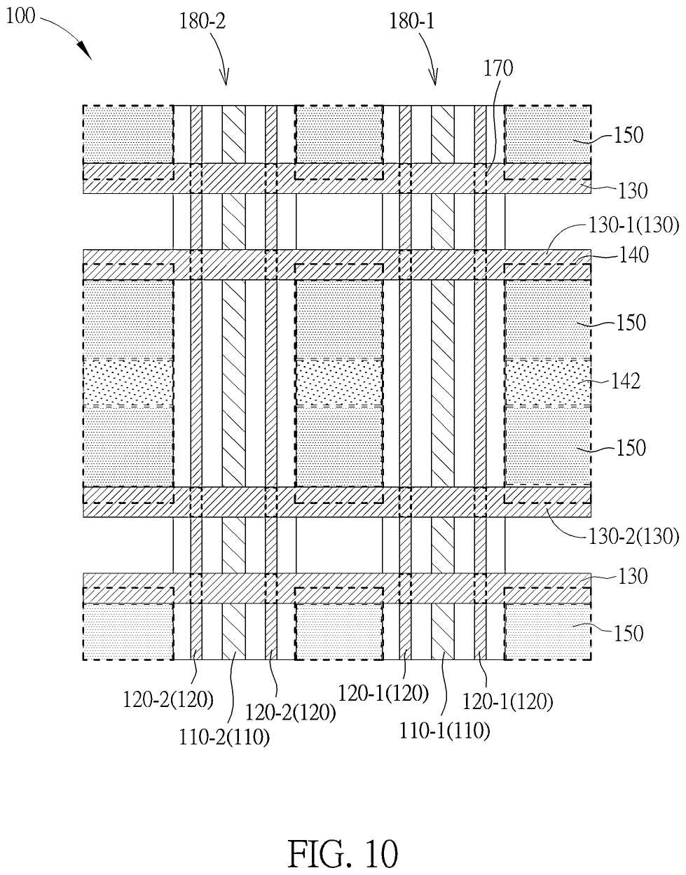

FIG. 6 is a schematic perspective view of a semiconductor device including two repeating units according to an embodiment of the present disclosure. FIG. 7 is a schematic cross-sectional view taken along section line EE′ of FIG. 6 according to an embodiment of the present disclosure. FIG. 10 is a schematic top view of a semiconductor device including at least two repeating units according to an embodiment of the present disclosure.

As shown in FIGS. 6, 7, and 10, the semiconductor device element 100 includes two repeating units, such as a repeating unit U1 and a repeating unit U2, and the structure and function of the repeating unit U1 and the repeating unit U2 are substantially the same. The number of the repeating units in the semiconductor device 100 is not limited to two, and can be any integer greater than 2, such as any number from 2 to 100 or any number between, depending on the actual needs. In addition, the repeating units can be disposed in a repeating manner along the first direction (for example, in the Y-direction) and/or the second direction (for example, in the X-direction) to present an array arrangement layout. FIG. 1 can be regarded as a partial perspective view of the repeating unit U1 in FIG. 2, and for the sake of brevity, identical components are not repeated.

As shown in FIGS. 6, 7 and 10, the repeating unit U1 at least includes a first trench 108-1, a first field plate 110-1, two first trench gates 120-1, a first planar gate 130-1, a second planar gate 130-2, two body doped regions 140 (referring to FIG. 10, the body doped regions 140 are respectively disposed on both sides of the first trench 108-1), two body contact regions 142 (referring to FIG. 10, the body contact regions 142 are respectively disposed on both sides of the first trench 108-1), four source doped regions 150 (referring to FIG. 10, each side of the first trench 108-1 includes source doped regions 150 disposed in pairs separately), a first conductive compound 160-1, a second conductive compound 160-2, a third conductive compound 160-3, and a plurality of the conductive contact structures 200. The second planar gate 130-2 is disposed on the first field plate 110-1 and the first trench gate 120-1 and parallel to the first planar gate 130-1.

As shown in FIGS. 6, 7 and 10, the repeating unit U2 at least includes a second trench 108-2, a second field plate 110-2, two second trench gates 120-2, a first planar gate 130-1, a second planar gate 130-2, two body doped regions 140 (referring to FIG. 10, the body doped regions 140 are respectively disposed on both sides of the second trench 108-2), two body contact regions 142 (referring to FIG. 10, the body contact regions 142 are respectively disposed on both sides of the second trench 108-2), four source doped regions 150 (referring to FIG. 10, each side of the second trench 108-2 includes source doped regions 150 disposed in pairs separately), a first conductive compound 160-1, a second conductive compound 160-2, a third conductive compound 160-3, and a plurality of conductive contact structures 200.

Referring to FIG. 7, in conjunction with FIGS. 6 and 10, the second trench 108-2 is disposed in the epitaxial layer 107 and extends along the first direction, such as the Y-direction. The second field plate 110-2 is disposed in the second trench 108-2 and extends along the first direction. The second trench gate 120-2 is disposed in the second recess 114-2 and extends along the first direction, and the second trench gate 120-2 is laterally separated from the second field plate 110-2. The top surface of the second field plate 110-2 is higher than the top surface of the second trench gate 120-2 in the region where the second conductive connection portion 170-2 is not provided. The second conductive connection portion 170-2 is disposed in the second trench 108-2 and located on the second trench gate 120-2. The first planar gate 130-1 and the second planar gate 130-2 extend continuously along the second direction (for example, in the X-direction) which is not parallel to the first direction (for example, substantially perpendicular) so that the first planar gate 130-1 and the second planar gate 130-2 extend across the top surfaces of the first field plate 110-1 and the first trench gate 120-1, and also extend across the top surfaces of the second field plate 110-2 and the second trench gate 120-2.

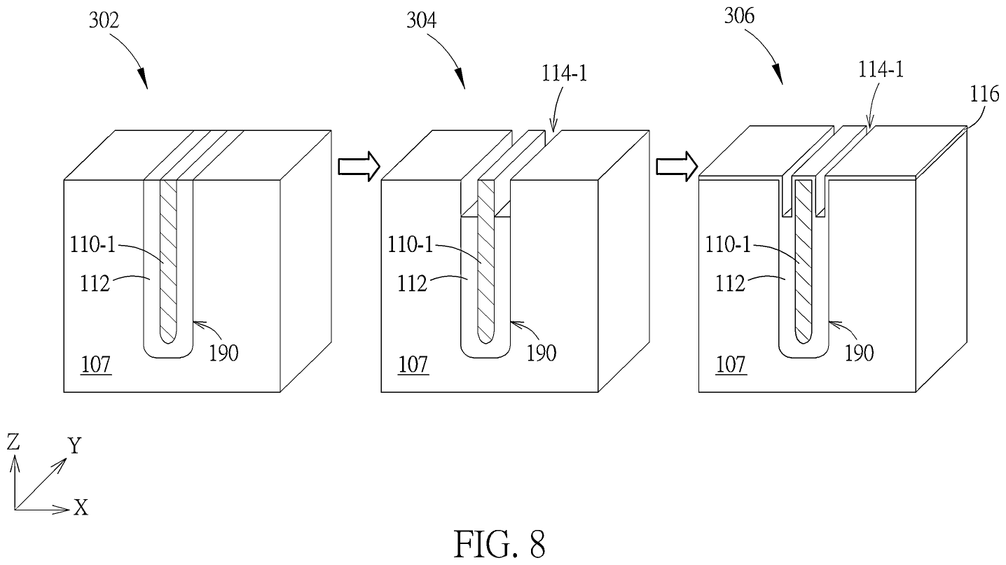

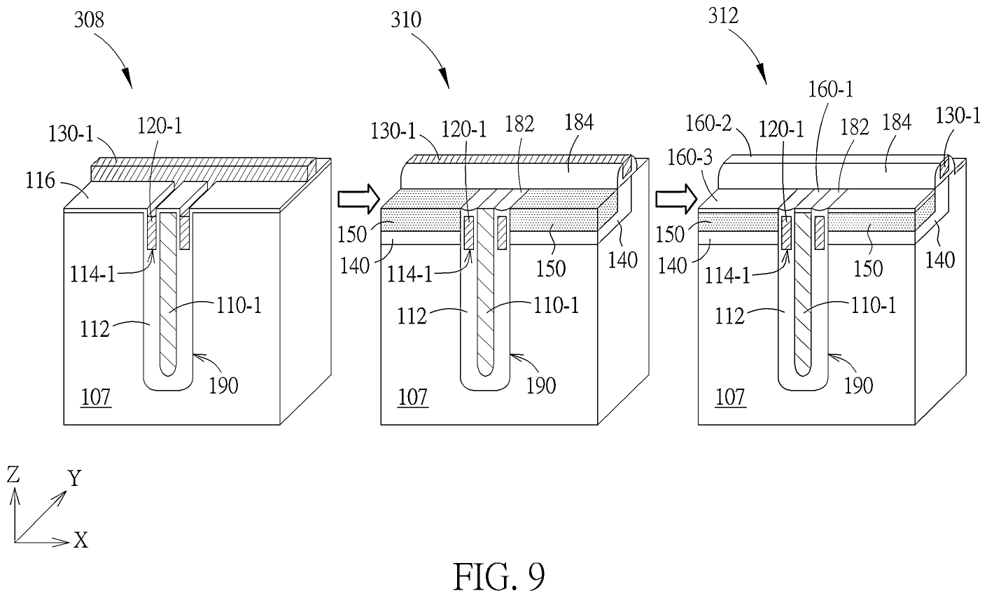

FIGS. 8 and 9 are schematic perspective views at various stages of a manufacturing method of a semiconductor device according to an embodiment of the present disclosure, and FIGS. 8 and 9 generally correspond to the perspective view of FIG. 1.

Referring to step 302 of FIG. 8, first, a first trench structure 190 is provided, which is located within the epitaxial layer 107 and extends along the first direction (Y-direction). The first trench structure 190 includes the first trench 108-1, the first field plate 110-1, and the trench dielectric layer 112. The first gate 110-1 is disposed in the first trench 108-1, and the trench dielectric layer 112 is disposed between the inner surface of the first trench 108-1 and the first gate 110-1.

Next, referring to step 304 of FIG. 8, the trench dielectric layer 112 is etched to thereby form at least one first recess 114-1, such as a pair of first recesses 114-1, each extending along the first direction.

Next, referring to step 306 of FIG. 8, a gate dielectric layer 116 is formed, and the gate dielectric layer 116 is disposed along the inner surface of the first recess 114-1 and the top surface of the first field plate 110-1. The gate dielectric layer 116 may be formed by performing a thermal oxidation process or a deposition process, but is not limited thereto.

Next, referring to step 308 of FIG. 9, a conductive layer (not shown) is formed to fill the first recess 114-1, and the conductive layer covers the first field plate 110-1 and the epitaxial layer 107. Then, the conductive layer is etched to form the first trench gate 120-1, the first planar gate 130-1, and the first conductive connection portion 170-1. The first trench gate 120-1 extends along the first direction and is laterally separated from the first field plate 110-1. The first trench gate 120-1 does not completely fill the first recess 114-1, so a trench gate cap layer 182 can be formed on the top surface of the first trench gate 120-1 in the subsequent process. The first planar gate 130-1 extends along the second direction (X-direction) which is not parallel to the first direction. The first planar gate 130-1 extends across the first field plate 110-1 and the first trench gate 120-1. The first conductive connection portion (not shown) is disposed in the first recess 114-1 and located between the first trench gate 120-1 and the first planar gate 130-1. The first trench gate 120-1 is electrically connected to the first planar gate 130-1 through the first conductive connection portion 170-1. A portion of the gate dielectric layer 116 is located between the first field plate 110-1 and the first planar gate 130-1, and another portion of the gate dielectric layer 116 is located between the trench dielectric layer 112 and the first trench gate 120-1.

By performing step 308, the process can be simplified since the first trench gate 120-1, the first planar gate 130-1, and the first conductive connection 170-1 can all be formed through the same deposition and etching processes.

Next, referring to step 310 of FIG. 9, the dielectric layer (not shown) is formed to fill the first recess 114-1. The dielectric layer covers the top surface of the first trench gate 120-1 and the side surface of the first planar gate 130-1. Then, the dielectric layer is etched to form the trench gate cap layer 182 and the planar gate spacer 184, where the trench gate cap layer 182 covers the top surface of the first trench gate 120-1 and the planar gate spacer 184 covers two opposite sides of the first planar gate 130-1. By providing the trench gate cap layer 182, the top surface of the first trench gate 120-1 can be protected in the subsequent process to prevent the first trench gate 120-1 from being electrically connected through the surface thereof to the conductive compound, such as the conductive compound (not shown) on the first field plate 110-1.

Next, as shown in step 310, the body doped regions 140 and the source doped regions 150 are formed in the upper portion of the epitaxial layer 107, and the source doped regions 150 are laterally (for example, on the XY plane) separated from the first trench gate 120-1 and the first planar gate 130-1.

Next, referring to step 312 of FIG. 9, a metal layer (not shown) is formed across the entire upper surface of the semiconductor device 100, that is, covering the first field plate 110-1, the first trench gate 120-1, the first planar gate 130-1, the trench gate cap layer 182, the planar gate spacer 184, and the source doped regions 150. Then, a heat treatment is performed, allowing the metal layer to react with the first field plate 110-1, the first planar gate 130-1, and the source doped regions 150. This reaction results in the formation of the conductive compounds 160, such as the first conductive compound 160-1, the second conductive compound 160-2, and the third conductive compound 160-3. Since the metal layer only reacts with the semiconductor material, but not with the dielectric layer (for example, the trench gate cap layer 182 and the planar gate spacer 184), the conductive compound 160 can be formed by self-alignment, thus it can be called a self-aligned conductive compound. Further, the first conductive compound 160-1 covers the first field plate 110-1, the second conductive compound 160-2 covers the first planar gate 130-1, and the third conductive compound 160-3 covers the source doped regions 150. The first conductive compound 160-1, the second conductive compound 160-2, and the third conductive compound 160-3 are laterally separated from each other.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
an epitaxial layer of a first conductivity type;
a first trench disposed in the epitaxial layer and extending along a first direction;
a first field plate disposed in the first trench and extending along the first direction;
a first trench gate disposed in the first trench and extending along the first direction, wherein the first trench gate is laterally separated from the first field plate, and a top surface of the first field plate is higher than a top surface of the first trench gate;
a first planar gate disposed above the first field plate and the first trench gate, and extending along a second direction not parallel to the first direction; and
a first conductive connection portion disposed in the first trench and located between the first trench gate and the first planar gate, wherein the first trench gate is electrically connected to the first planar gate through the first conductive connection portion.

2. The semiconductor device according to claim 1, further comprising a first conductive compound covering the top surface of the first field plate, and extending along the first direction.

3. The semiconductor device according to claim 1, further comprising:
a trench gate cap layer disposed in the first trench, wherein the trench gate cap layer covers a top surface of the first trench gate and a side surface of the first conductive connection portion.

4. The semiconductor device according to claim 3, further comprising:
a planar gate spacer disposed on the first trench and extending along the second direction, wherein materials of the planar gate spacer and the trench gate cap layer are the same.

5. The semiconductor device according to claim 3, wherein the trench gate cap layer comprises a recessed top surface.

6. A semiconductor device of claim 1, further comprising:
a second conductive compound covering a top surface of the first planar gate and extending along the second direction.

7. The semiconductor device according to claim 2, further comprising:
a source doped region disposed in the upper portion of the epitaxial layer and abutting the first trench, the source doped region being of the first conductivity type; and
a third conductive compound covering a top surface of the source doped region and laterally separated from the first trench gate and the first conductive compound.

8. The semiconductor device according to claim 7, further comprising:
a body doped region disposed below the source doped region, wherein a portion of the body doped region covers a side surface of the first trench gate in the second direction, and another portion of the body doped region is covered by the first planar gate in a vertical direction.

9. The semiconductor device according to claim 1, further comprising:
a trench dielectric layer disposed in the first trench and located between an inner surface of the first trench and the first field plate; and
a first recess disposed in the first trench and located above the trench dielectric layer,
wherein the first trench gate is disposed in the first recess.

10. The semiconductor device according to claim 1, further comprising:
a second trench disposed in the epitaxial layer and extending along the first direction;
a second field plate disposed in the second trench and extending along the first direction;
a second trench gate disposed in the second trench and extending along the first direction, wherein the second trench gate is laterally separated from the second field plate, and a top surface of the second field plate is higher than a top surface of the second trench gate;
a second conductive connection portion disposed in the second trench and located on the second trench gate; and
a first conductive compound covering the top surface of the second field plate and extending along the first direction,
wherein the first planar gate is further disposed on the second field plate and the second trench gate.

11. The semiconductor device according to claim 1, wherein two first trench gates are disposed in the first trench, and both first trench gates are respectively laterally separated from two opposite sides of the first field plate, and the top surface of the first field plate is higher than both top surfaces of both first trench gates.

12. The semiconductor device according to claim 11, further comprising:
two first conductive connection portions respectively disposed on two opposite sides of the first field plate, and each located between the first planar gate and corresponding one of the first trench gates, wherein the first trench gates are electrically connected to the first planar gate through corresponding one of the first conductive connection portions.

13. The semiconductor device according to claim 1, further comprising:
a second planar gate disposed over the first field plate and the first trench gate, and parallel to the first planar gate;
a body doped region disposed beneath the first planar gate and the second planar gate, wherein a portion of the body doped region overlaps the first planar gate, and another portion of the body doped region overlaps the second planar gate, the body doped region being of a second conductivity type opposite the first conductivity type; and
two source doped regions disposed in the body doped region and abutting the first trench, and separated from each other along the first direction, the source doped regions being of the first conductivity type, wherein one of the source doped regions is adjacent to the first planar gate, and another one of the source doped region is adjacent to the second planar gate.

14. The semiconductor device according to claim 13, further comprising a single conductive compound covering the source doped regions that are separated from each other.

15. A method of manufacturing a semiconductor device, comprising:
providing a first trench structure, the first trench structure being located in an epitaxial layer and extending along a first direction, the first trench structure comprising:
a first trench;
a first field plate disposed in the first trench; and
a trench dielectric layer disposed between the first trench and the first field plate;
etching the trench dielectric layer to form a first recess extending along the first direction;
forming a conductive layer to fill the first recess, wherein the conductive layer covers the first field plate and the epitaxial layer; and
etching the conductive layer to form a first trench gate, a first planar gate, and a first conductive connection portion, wherein:
the first trench gate extends along the first direction and laterally separates from the first field plate,
the first planar gate extends along a second direction not parallel to the first direction, wherein the first planar gate disposed on the first field plate and the first trench gate,
the first conductive connection portion is disposed in the first recess and located between the first trench gate and the first planar gate.

16. The method of manufacturing a semiconductor device according to claim 15, wherein the first trench gate is electrically connected to the first planar gate through the first conductive connection portion.

17. The method of manufacturing a semiconductor device according to claim 15, further comprising:
before forming the conductive layer, forming a gate dielectric layer, wherein the gate dielectric layer is disposed along an inner surface of the first recess and a top surface of the first field plate; and
after forming the conductive layer, a portion of the gate dielectric layer being located between the first field plate and the first planar gate, and another portion of the gate dielectric layer being located between the trench dielectric layer and the first trench gate.

18. The method of manufacturing a semiconductor device according to claim 15, after etching the conductive layer, further comprising:
forming a dielectric layer to fill the first recess, wherein the dielectric layer covers a top surface of the first trench gate and a side surface of the first planar gate; and
etching the dielectric layer to form a trench gate cap layer and a planar gate spacer, wherein the trench gate cap layer covers the top surface of the first trench gate, and the planar gate spacer covers the side surface of the first planar gate.

19. The method of manufacturing a semiconductor device according to claim 18, after forming the trench gate cap layer and the planar gate spacer, further comprising:
forming a metal layer covering the first field plate, the first trench gate, the first planar gate, the trench gate cap layer, and the planar gate spacer; and
performing a heat treatment to cause the metal layer to react with the first field plate and the first planar gate, thereby forming a first conductive compound and a second conductive compound, wherein the first conductive compound covers the first field plate, the second conductive compound covers the first planar gate, and the first conductive compound and the second conductive compound are laterally separated from each other.

20. The method of manufacturing a semiconductor device according to claim 18, further comprising:
after forming the trench gate cap layer and the planar gate spacer, forming a source doped region in an upper portion of the epitaxial layer, wherein the source doped region is laterally separated from the first trench gate and the first planar gate;
when forming the metal layer, the metal layer further covers the source doped region; and
when performing the heat treatment, the metal layer further reacts with the source doped region to form a third conductive compound, wherein the third conductive compound, the second conductive compound, and the first conductive compound are laterally separated from each other.
